(19) United States
(12) Patent Application Publication
(10) Pub. No.: US 2015/0137318 A1
(43) Pub. Date: May 21, 2015

(54) SEMICONDUCTOR WAFER, METHOD OF PRODUCING A SEMICONDUCTOR WAFER AND METHOD OF PRODUCING A COMPOSITE WAFER

(71) Applicants: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP)

(72) Inventors: Takenori OSADA, Tsukuba-shi (JP); Tomoyuki TAKADA, Tsukuba-shi (JP); Masahiko HATA, Phoenix, AZ (US); Tetsuji YASUDA, Tsukuba-shi (JP); Tatsuro MAEDA, Tsukuba-shi (JP); Taro ITATANI, Tsukuba-shi (JP)

(73) Assignees: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP)

(21) Appl. No.: 14/568,189

(22) Filed: Dec. 12, 2014

Related U.S. Application Data
(63) Continuation-in-part of application No. PCT/JP2013/003754, filed on Jun. 14, 2013.

(30) Foreign Application Priority Data
Jun. 15, 2012 (JP) 2012-136448

(51) Int. Cl. H01L 29/267; H01L 21/306; H01L 21/02; H01L 29/16; H01L 29/20

(52) U.S. Cl. CPC H01L 29/267; H01L 29/16; H01L 29/20; H01L 21/02524; H01L 21/02546; H01L 21/02441; H01L 21/02463; H01L 21/30604
USPC 257/615; 438/455

(57) ABSTRACT

A semiconductor wafer is provided. The semiconductor wafer comprises a sacrificial layer, a first semiconductor crystal layer, and a second semiconductor crystal layer above a semiconductor crystal layer forming wafer, wherein the semiconductor crystal layer forming wafer, the sacrificial layer, the first semiconductor crystal layer and the second semiconductor crystal layer are arranged in the order of the semiconductor crystal layer forming wafer, the sacrificial layer, the first semiconductor crystal layer and the second semiconductor crystal layer, a first atom of one type selected from a plurality of types of atoms constituting the semiconductor crystal layer forming wafer or the sacrificial layer is contained in the first semiconductor crystal layer and the second semiconductor crystal layer as an impurity, and the concentration of the first atom in the second semiconductor crystal layer is lower than the concentration of the first atom in the first semiconductor crystal layer.

The contents of the following patent applications are incorporated herein by reference:
NO. 2012-13648 filed in Japan on Jun. 15, 2012, and
NO. PCT/JP2013/003754 filed on Jun. 14, 2013.

### BACKGROUND

1. Technical Field

The present invention relates to a semiconductor wafer, a method of producing a semiconductor wafer, and a method of producing a composite wafer.

2. Related Art

Group III-V compound semiconductors such as GaAs and InGaAs have high electron mobility. On the other hand, Group IV semiconductors such as Ge and SiGe have high hole mobility. Therefore, a highly advanced complementary metal-oxide-semiconductor field effect transistor (CMOSFET) can be realized if the Group III-V compound semiconductors are used to form an N-channel metal-oxide-semiconductor field effect transistor (MOSFET) (hereinafter, may be simply referred to as nMOSFET) and the Group IV semiconductors are used to form a P-channel MOSFET (hereinafter, may be simply referred to as “pMOSFET”). Non-Patent Document 1 discloses a CMOSFET structure in which an N-channel MOSFET having a channel made of a Group III-V compound semiconductor and a P-channel MOSFET having a channel made of Ge are formed on a single wafer.

To form heterogeneous materials of a Group III-V compound semiconductor layer and a Group IV semiconductor crystal layer on a single wafer (for example, a silicon wafer), a technique is known to transfer onto the single wafer a semiconductor crystal layer that has been formed on a crystal growth wafer. For example, Non-Patent Document 2 discloses a technique according to which an AlAs layer is formed as a sacrificial layer on a GaAs wafer and a Ge layer is formed on the sacrificial layer (AlAs layer) and transferred onto a silicon wafer.

### PRIOR ART DOCUMENTS

### Non-Patent Documents

Non-Patent Document 1: S. Takagi, et al., SSE, vol. 51, pp. 526-536, 2007.
Non-Patent Document 2: Y. Bai and E. A. Fitzgerald, ECS Transactions, 33 (6) 927-932 (2010)

To form on a single wafer an N-channel metal-insulator-semiconductor field effect transistor (MISFET) (hereinafter, may be simply referred to as “nMISFET”) having a channel made of a Group III-V compound semiconductor and a P-channel MISFET (hereinafter, may be simply referred to as “pMISFET”) having a channel made of a Group IV semiconductor, it is necessary to develop a technique of forming the Group III-V compound semiconductor for the n-MISFET and the Group IV semiconductor for the p-MISFET on the single wafer. Furthermore, taking into consideration that the single wafer is produced as a large scale integration (LSI), it is preferable to form a Group III-V compound semiconductor crystal layer for the nMISFET and a Group IV semiconductor crystal layer for the pMISFET on a silicon wafer, which makes it possible to make use of existing production apparatuses and methods.

In some cases, a semiconductor crystal layer for transfer is formed by: using a Group III-V compound single crystal wafer such as GaAs as a semiconductor crystal layer forming wafer; using a Group III-V compound semiconductor crystal layer such as AlAs as a sacrificial layer for peeling off a semiconductor crystal layer from the semiconductor crystal layer forming wafer by etching; and performing epitaxial growth of a Group IV semiconductor such as Ge. In some cases, a Group III atom such as Ga and a Group V atom such as As serve as a donor or an acceptor inside a Group IV semiconductor such as Ge. Accordingly, when a semiconductor crystal layer is formed by epitaxial growth, it is necessary to avoid, as much as possible, mixing of an unintended impurity atom from a semiconductor crystal layer forming wafer or a sacrificial layer.

An object of the present invention is to inhibit mixing of an unintended impurity atom into a semiconductor crystal layer when a semiconductor crystal layer for transfer is formed by epitaxial growth.

### SUMMARY

To solve the above-mentioned problems, a first aspect of the present invention provides a semiconductor wafer comprising a sacrificial layer, a first semiconductor crystal layer, and a second semiconductor crystal layer above a semiconductor crystal layer forming wafer, wherein the semiconductor crystal layer forming wafer, the sacrificial layer, the first semiconductor crystal layer and the second semiconductor crystal layer are arranged in the order of the semiconductor crystal layer forming wafer, the sacrificial layer, the first semiconductor crystal layer and the second semiconductor crystal layer, a first atom of one type selected from a plurality of types of atoms constituting the semiconductor crystal layer forming wafer or the sacrificial layer is contained in the first semiconductor crystal layer and the second semiconductor crystal layer as an impurity, and the concentration of the first atom in the second semiconductor crystal layer is lower than the concentration of the first atom in the first semiconductor crystal layer.

The semiconductor wafer may further comprise a diffusion inhibiting layer that inhibits diffusion of the first atom at any cross-sectional position between (a) the interface of the semiconductor crystal layer forming wafer that faces the sacrificial layer and (b) a middle of the second semiconductor crystal layer. Examples of the semiconductor crystal layer forming wafer include a single-crystal GaAs wafer and a single-crystal Ge wafer, examples of the sacrificial layer include a Group III-V semiconductor layer, and examples of the first semiconductor crystal layer and the second semiconductor crystal layer include a Group IV semiconductor layer. Specifically, examples of the sacrificial layer include a layer that is made of AlₐGa_{b}In_{(l-a-b)}As (0.9≦a≦1, 0≦b≦0.1, 0.9≦a+b≦1), and examples of the first semiconductor crystal layer and the second semiconductor crystal layer include a layer that is made of C_{d}SiₑGe_{f}Sn_{(1-d-e-f)} (0≦d<1, 0≦e<1, 0<f≦1, 0<d+e+f≦1). More specifically, examples of the sacrificial layer include a single-crystal AlAs layer, examples of the first semiconductor crystal layer and the second semiconductor crystal layer include a single-crystal Ge layer, and in this case, examples of the first atom include an Al, Ga or As atom. The concentration of a Ga atom in the second semiconductor crystal layer is preferably lower than 2×10¹⁷ [atom/cm³]. The half-value width of the diffraction spectrum of the (004) plane of the second semiconductor crystal layer that is made of the single-crystal Ge is, for example, 40 arcsec or lower when measured using X-ray diffraction. The second semiconductor crystal layer exhibits flatness of, for example, 2 nm or less when expressed in terms of the root mean square (RMS).

A second aspect of the present invention provides a method of producing a semiconductor wafer, comprising: forming a sacrificial layer and a first semiconductor crystal layer in the order of the sacrificial layer and the first semiconductor crystal layer by epitaxial growth above a semiconductor crystal layer forming wafer; reducing a residual impurity atom resulting from the epitaxial growth after the formation of the sacrificial layer and the first semiconductor crystal layer; and forming a second semiconductor crystal layer above the first semiconductor crystal layer by epitaxial growth after the reduction of the residual impurity atom.

The reduction of the residual impurity atom is achieved, for example, by internal cleaning of an epitaxial growth furnace that is used for the epitaxial growth for the formation of the sacrificial layer and the first semiconductor crystal layer and the epitaxial growth for the formation of the second semiconductor crystal layer. The internal cleaning of the epitaxial growth furnace may be performed after the semiconductor crystal layer forming wafer is transferred to a spare chamber. In this case, the semiconductor crystal layer forming wafer may be transferred to the epitaxial growth furnace from the spare chamber after the internal cleaning of the epitaxial growth furnace is completed. The reduction of the residual impurity atom may be performed, for example, by transferring the semiconductor crystal layer forming wafer from a first epitaxial growth furnace used for the epitaxial growth for the formation of the sacrificial layer and the first semiconductor crystal layer to a second epitaxial growth furnace used for the epitaxial growth for the formation of the second semiconductor crystal layer. The growth temperature at which the epitaxial growth is performed for forming the second semiconductor crystal layer is, for example, higher than the growth temperature at which the epitaxial growth is performed for forming the first semiconductor crystal layer. The reaction pressure under which the epitaxial growth is performed for forming the second semiconductor crystal layer is, for example, lower than the reaction pressure under which the epitaxial growth is performed for forming the first semiconductor crystal layer. The method may further comprise, prior to or during the formation of the sacrificial layer and the first semiconductor crystal layer, or between the formation of the sacrificial layer and the first semiconductor crystal layer and the reduction of the residual impurity atom, forming a diffusion inhibiting layer to inhibit diffusion of a first atom of one type selected from a plurality of types of atoms constituting the sacrificial layer or the semiconductor crystal layer forming wafer.

A third aspect of the present invention provides a method of producing a composite wafer using the semiconductor wafer produced by the method as set forth in the second aspect, comprising: bonding the semiconductor wafer and a transfer target wafer in such a manner that a first surface of the semiconductor wafer faces a second surface of the transfer target wafer, the first surface being a surface of the second semiconductor crystal layer or a surface of a layer formed above the second semiconductor crystal layer, the first surface being designed to be brought into contact with the transfer target wafer or a layer formed on the transfer target wafer, the second surface being a surface of the transfer target wafer or a surface of the layer formed on the transfer target wafer, and the second surface being designed to be brought into contact with the first surface; and etching the sacrificial layer by entirely or partly immersing the semiconductor wafer and the transfer target wafer into an etching solution so that the transfer target wafer and the semiconductor wafer are separated from each other with the first semiconductor crystal layer and the second semiconductor crystal layer being left on the transfer target wafer.

The summary clause does not necessarily describe all necessary features of the embodiments of the present invention. The present invention may also be a sub-combination of the features described above.

### BRIEF DESCRIPTION OF THE DRAWINGS

FIG. 1 is a cross-sectional view illustrating a semiconductor wafer 100 relating to a first embodiment.

FIG. 2 is a cross-sectional view illustrating a modification of the semiconductor wafer 100.

FIG. 3 is a cross-sectional view illustrating a modification of the semiconductor wafer 100.

FIG. 4 is a cross-sectional view illustrating a modification of the semiconductor wafer 100.

FIG. 5 is a flowchart illustrating an example of steps for producing the semiconductor wafer 100.

FIG. 6 is a flowchart illustrating another example of steps for producing the semiconductor wafer 100.

FIG. 7 is a cross-sectional view illustrating steps of a method of producing a composite wafer relating to a third embodiment in the performed order.

FIG. 8 is a cross-sectional view illustrating steps of a method of producing a composite wafer relating to a third embodiment in the performed order.

FIG. 9 is a cross-sectional view illustrating steps of a method of producing a composite wafer relating to a third embodiment in the performed order.

FIG. 10 is a cross-sectional view illustrating steps of a method of producing a composite wafer relating to a third embodiment in the performed order.

FIG. 11 is a graph showing a result of secondary ion mass spectrum analysis of a semiconductor crystal layer forming wafer 102 in Example 1.

FIG. 12 is a graph showing a relationship between the growth temperature and the number of pits in the semiconductor crystal layer forming wafer 102 of Example 6.

FIG. 13 is a graph showing a relationship between the film thickness and the mobility in the semiconductor crystal layer forming wafer 102 of Example 7.

### DESCRIPTION OF EXEMPLARY EMBODIMENTS

Hereinafter, (some) embodiment(s) of the present invention will be described. The embodiment(s) do(es) not limit the invention according to the claims, and all the combinations of the features described in the embodiment(s) are not necessarily essential to means provided by aspects of the invention.

### First Embodiment

FIG. 1 is a cross-sectional view illustrating a semiconductor wafer 100 relating to a first embodiment. The semiconductor wafer 100 is a semiconductor wafer that can be used when a composite wafer having a semiconductor crystal layer is formed by epitaxial lift-off. The semiconductor wafer 100 includes a semiconductor crystal layer forming wafer 102, a sacrificial layer 104, a second semiconductor crystal layer 106, a first semiconductor crystal layer 107, and a diffusion inhibiting layer 108. The semiconductor crystal layer forming wafer 102, the sacrificial layer 104, the second semiconductor crystal layer 106, the first semiconductor crystal layer 107, and the diffusion inhibiting layer 108 are positioned in the order of the semiconductor crystal layer forming wafer 102, the sacrificial layer 104, the diffusion inhibiting layer 108, the first semiconductor crystal layer 107, and the second semiconductor crystal layer 106.

The semiconductor crystal layer forming wafer 102 is a wafer used to form a high-quality second semiconductor crystal layer 106. A preferable material of the semiconductor crystal layer forming wafer 102 depends on the material of the second semiconductor crystal layer 106, the method of forming the second semiconductor crystal layer 106, and the like. Generally speaking, the semiconductor crystal layer forming wafer 102 is desirably made of a material that lattice-matches or pseudo-lattice-matches the second semiconductor crystal layer 106 to be formed. For example, when a GaAs layer is formed by epitaxial growth as the second semiconductor crystal layer 106, the semiconductor crystal layer forming wafer 102 is preferably a GaAs single-crystal wafer, and can be selected among InP, sapphire, Ge and SiC single-crystal wafers. When the semiconductor crystal layer forming wafer 102 is a GaAs single-crystal layer, the plane on which the second semiconductor crystal layer 106 is formed is the (100) plane or (111) plane.

The sacrificial layer 104 is a layer that is used to separate the semiconductor crystal layer forming wafer 102 from the second semiconductor crystal layer 106. Since the sacrificial layer 104 is removed by etching, the second semiconductor crystal layer 106 is separated from the semiconductor crystal layer forming wafer 102. When the sacrificial layer 104 is etched, it is necessary to prevent at least a portion of the semiconductor crystal layer forming wafer 102 and the second semiconductor crystal layer 106 from being etched away and to keep such a portion. Therefore, the etching rate of the sacrificial layer 104 needs to be higher than the etching rate of the semiconductor crystal layer forming wafer 102 and the second semiconductor crystal layer 106, preferably several times or more. Examples of a material for the sacrificial layer 104 include a Group III-V compound semiconductor, and specifically, AlₐGa_{b}In_{(1-a-b)}As (0.9≦a≦1, 0≦b≦0.1, 0.9≦a+b≦1). When the semiconductor crystal layer forming wafer 102 is a GaAs single crystal wafer, and the second semiconductor crystal layer 106 is a GaAs layer, the sacrificial layer 104 is preferably an AlAs layer. The sacrificial layer 104 may be selected among an InAlAs layer, an InCap layer, an InAlP layer, an InGaAlP layer, an AlSb layer, and an AlGaAs layer. As the thickness of the sacrificial layer 104 increases, the crystallinity of the second semiconductor crystal layer 106 tends to degrade. Therefore, the sacrificial layer 104 is preferably as thin as possible as long as the sacrificial layer 104 can serve as a sacrificial layer. The thickness of the sacrificial layer 104 can be selected within the range of 0.1 nm to 10 μm. When the semiconductor crystal layer forming wafer 102 is a GaAs single crystal wafer, and the sacrificial layer 104 is an AlAs layer, the thickness of the sacrificial layer 104 is preferably 0.1 nm to 2 μm. When the thickness of the sacrificial layer 104 is larger than 2 μm, dislocations are likely formed in a crystal due to the difference between the lattice constant of the GaAs single crystal wafer and the lattice constant of the AlAs layer; thus, it is not preferred.

The second semiconductor crystal layer 106 is a transfer layer that is to be transferred onto a transfer target wafer (described later). The second semiconductor crystal layer 106 is used as, for example, an active layer of a semiconductor device. The second semiconductor crystal layer 106 can have high-quality crystallinity by being formed on the semiconductor crystal layer forming wafer 102 by epitaxial growth or the like. Furthermore, since the second semiconductor crystal layer 106 is formed by being transferred onto the transfer target wafer, the second semiconductor crystal layer 106 having high quality can be formed on any transfer target wafer without the need of considering whether the second semiconductor crystal layer 106 lattice matches the transfer target wafer.

The first semiconductor crystal layer 107 is formed before the second semiconductor crystal layer 106 is formed. The second semiconductor crystal layer 106 is a crystal layer made of a material similar to that of the second semiconductor crystal layer 106. As described later, in production of the semiconductor wafer 100, before the second semiconductor crystal layer 106 is formed, a measure is taken to reduce a residual impurity atom in epitaxial growth. That is, the reduction of the residual impurity atom at a start of the epitaxial growth for the formation of the second semiconductor crystal layer 106 is achieved, when compared with the residual impurity atom resulting from the epitaxial growth for the formation of the first semiconductor crystal layer 107. The measure may be cleaning of a reaction furnace, or alternatively may be a measure of separately providing a reaction furnace for forming the first semiconductor crystal layer 107 and a reaction furnace for forming the second semiconductor crystal layer 106, or other measures. While the measure is taken, it is necessary to protect layers that have already been formed. The first semiconductor crystal layer 107 serves as a cap layer for protecting the layers that have already been formed. Accordingly, the first semiconductor crystal layer 107 is not expected to have high purity and high quality. For example, the quality of the first semiconductor crystal layer 107 in terms of purity, crystallinity, surface flatness, etc. is lower than that of the second semiconductor crystal layer 106. However, surface roughness, etc. of the first semiconductor crystal layer 107 that may lower the crystallinity of the second semiconductor crystal layer 106 is not preferred. The first semiconductor crystal layer 107 is required to have crystal quality that keeps high the crystallinity of an epitaxial layer (the second semiconductor crystal layer 106 in the present example) formed on an upper layer. For example, the first semiconductor crystal layer 107 has quality in terms of purity, crystallinity, surface flatness, etc. that is higher than those of the sacrificial layer 104 and the diffusion inhibiting layer 108.

The second semiconductor crystal layer 106 and the first semiconductor crystal layer 107 contain, as an impurity, a first atom of one type selected from a plurality of types of atoms constituting the semiconductor crystal layer forming wafer 102 or the sacrificial layer 104. The concentration of the first atom in the second semiconductor crystal layer 106 is lower than the concentration of the first atom in the first semiconductor crystal layer 107. When the first atom is a Ga atom, examples of the concentration of a Ga atom in the second semiconductor crystal layer 106 include less than 2×10¹⁷ [atoms/cm³]. The profile according to the value of the concentration of the first atom and the layer configuration can be realized by a production method described later.

Examples of the second semiconductor crystal layer 106 and the first semiconductor crystal layer 107 include a crystal layer made of a Group III-V compound semiconductor, a crystal layer made of a Group IV semiconductor, a crystal layer made of a Group II-VI compound semiconductor, or a laminate obtained by laminating a plurality of these crystal layers. Examples of the Group III-V compound semiconductor include AlᵤGaᵥIn₁₋ᵤ₋ᵥNₘPₙAs_{g}Sb_{1-m-n-q} (0≦u≦1, 0≦v≦1, 0≦m≦1, 0≦n≦1, 0≦q≦1), for example, GaAs, In_{y}Ga_{1-y}As (0<y<1), InP and GaSb. Examples of the Group IV semiconductor include C_{d}SiₑGe_{f}Sn_{(1-d-e-f)} (0≦d<1, 0≦e<1, 0<f≦1, 0<d+e+f≦1). Specifically, d=0 for example. That is, the examples include SiₑGe_{f}Sn_{(1-e-f)} (0≦e<1, 0<f≦1, 0<e+f≦1). More specifically, d=(1−e−F)=0 for example. That is, examples include GeₓSi₁₋ₓ (0<x≦1). Further specifically, x=1 for example. That is, the examples include Ge. Examples of the Group II-VI compound semiconductor include ZnO, ZnSe, ZnTe, CdS, CdSe and CdTe. When the Group IV semiconductor is GeₓSi₁₋ₓ (0<x<1), the Ge composition ratio x of GeₓSi₁₋ₓ is preferably 0.9 or higher. With the Ge composition ratio x that is 0.9 or higher, semiconductor characteristics similar to those of Ge can be obtained. By using the above-mentioned crystal layers or the laminate as the second semiconductor crystal layer 106, the second semiconductor crystal layer 106 can be used for an active layer of a high mobility field effect transistor, and particularly of a high mobility complementary field effect transistor.

The respective thickness of the second semiconductor crystal layer 106 and the first semiconductor crystal layer 107 can be appropriately selected within the range of 0.1 nm to 500 μm. The thickness of the second semiconductor crystal layer 106 is preferably no less than 0.1 nm and less than 1 μm. When the thickness of the second semiconductor crystal layer 106 is less than 1 μm, the second semiconductor crystal layer 106 can be used to form a composite wafer that is suitably used to produce a highly advanced transistor such as ultrathin-body MISFET. When the semiconductor crystal layer forming wafer 102 is a GaAs single crystal wafer, and the first semiconductor crystal layer 107 and the second semiconductor crystal layer 106 are Ge layers, the total of the thickness of the first semiconductor crystal layer 107 and the thickness of the second semiconductor crystal layer 106 is preferably 0.2 nm to 10 μm. When the total thickness is larger than 10 μm, dislocations are likely formed in a crystal of the second semiconductor crystal layer 106 due to the difference between the lattice constant of the GaAs single crystal wafer and the lattice constant of the Ge layer; thus, it is not preferred. When it is desired to lower the background carrier concentration in the second semiconductor crystal layer 106, the thickness of the second semiconductor crystal layer 106 is preferably 2 to 6 μm.

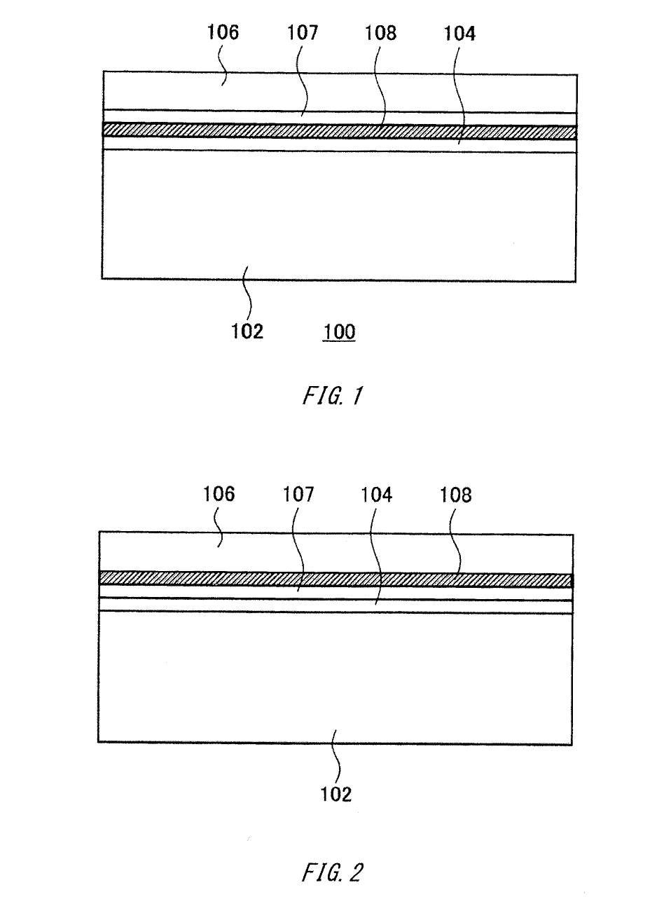

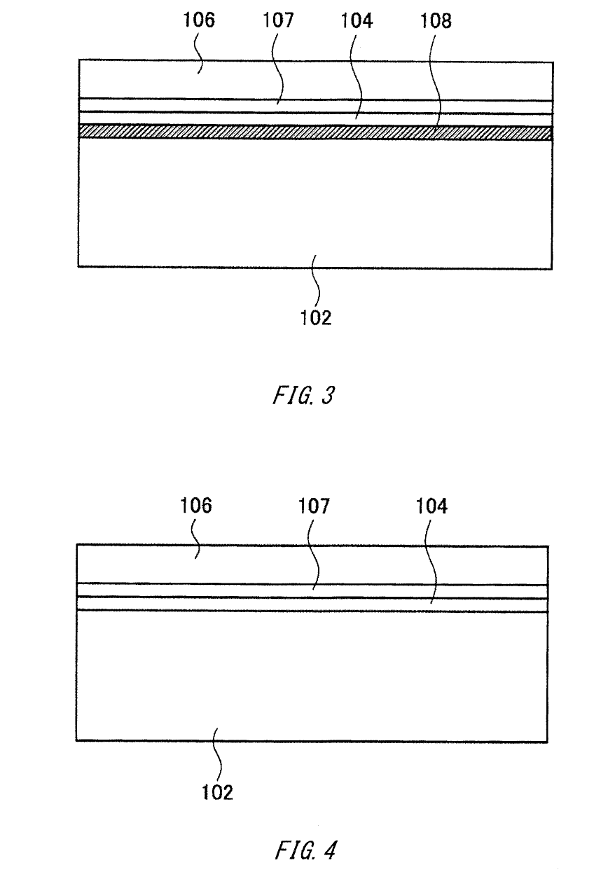

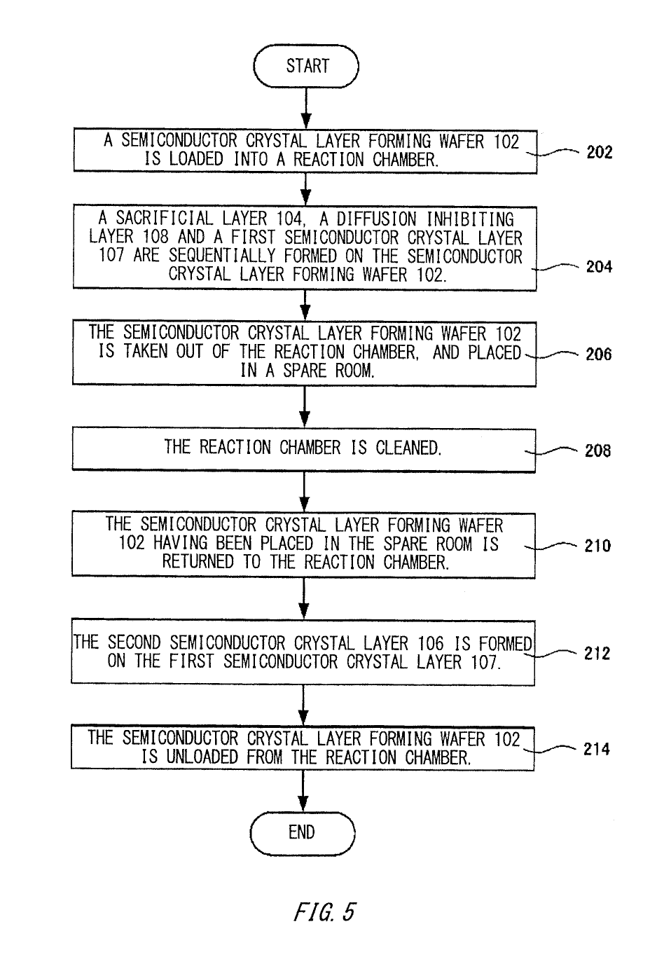

The diffusion inhibiting layer 108 inhibits diffusion of a first atom of one type selected from a plurality of types of atoms constituting the semiconductor crystal layer forming wafer 102 or the sacrificial layer 104. The diffusion inhibiting layer 108 can be formed at any cross-sectional position between (a) the interface of the semiconductor crystal layer forming wafer 102 that faces the sacrificial layer 104 and (b) a middle of the second semiconductor crystal layer 106. FIG. 1 illustrates the semiconductor wafer 100 in which the diffusion inhibiting layer 108 is positioned between the sacrificial layer 104 and the second semiconductor crystal layer 106. Other than this, as illustrated in FIG. 2, the diffusion inhibiting layer 108 may be positioned between the first semiconductor crystal layer 107 and the second semiconductor crystal layer 106, or as illustrated in FIG. 3, the diffusion inhibiting layer 108 may be positioned between the semiconductor crystal layer forming wafer 102 and the sacrificial layer 104. Note that the diffusion inhibiting layer 108 may be omitted as illustrated in FIG. 4.

The diffusion inhibiting layer 108, when present, can inhibit diffusion of a first atom from the semiconductor crystal layer forming wafer 102. Because the first atom in many cases serves as a donor or an acceptor in the second semiconductor crystal layer 106, it becomes a factor to lower the performance of the second semiconductor crystal layer 106. However, by forming the diffusion inhibiting layer 108, entrance of the first atom into the second semiconductor crystal layer 106 can be inhibited, and a high quality second semiconductor crystal layer 106 can be provided. When the diffusion inhibiting layer 108 is formed between the sacrificial layer 104 and the second semiconductor crystal layer 106 as illustrated in FIG. 1 or 2, diffusion of the first atom from the sacrificial layer 104 can be inhibited, and the quality of the second semiconductor crystal layer 106 can be further enhanced. Examples of a material for the diffusion inhibiting layer 108 include InGaP, InAlP and SiGe.

When the semiconductor crystal layer forming wafer 102 or the sacrificial layer 104 contains a Group V atom, the diffusion inhibiting layer 108 is preferably a Group III-V semiconductor crystal layer having a Group V atom whose atomic radius is smaller than that of the Group V atom contained in the semiconductor crystal layer forming wafer 102 or the sacrificial layer 104. For example, when the Group V atom contained in the semiconductor crystal layer forming wafer 102 or the sacrificial layer 104 is an As atom, the diffusion inhibiting layer 108 preferably consists of a Group III-V semiconductor containing P that is a Group V atom whose atomic radius is smaller than that of an As atom, for example InGaP. When the diffusion inhibiting layer 108 is a Group III-V semiconductor crystal layer containing a Group V atom whose atomic radius is smaller than that of the Group V atom contained in the semiconductor crystal layer forming wafer 102 or the sacrificial layer 104, the binding energy among the Group III-V atoms in the diffusion inhibiting layer 108 can be made higher. By making the binding energy in the diffusion inhibiting layer 108 higher, the ability to inhibit diffusion of the first atom can be enhanced.

Examples of the sacrificial layer 104 include a Group III-V semiconductor, and examples of the second semiconductor crystal layer 106 include a Group IV semiconductor. For example, when the semiconductor crystal layer forming wafer 102 is made of single crystal GaAs or single crystal Ge, the sacrificial layer 104 is made of single crystal AlAs, the first semiconductor crystal layer 107 and the second semiconductor crystal layer 106 are made of single crystal Ge, and the diffusion inhibiting layer 108 is made of single crystal InGaP, examples of the first atom include an Al atom, a Ga atom and an As atom.

When the diffusion inhibiting layer 108 is positioned between the sacrificial layer 104 and the second semiconductor crystal layer 106 or between the second semiconductor crystal layer 106 and the first semiconductor crystal layer 107, the semiconductor crystal layer forming wafer 102 or the sacrificial layer 104 may contain one or more atoms selected from a Ga atom and an As atom. In this case, the diffusion inhibiting layer 108 is preferably a Group III-V semiconductor crystal layer constituted with a Group III atom and a Group V atom other than a Ga atom and an As atom. Because the diffusion inhibiting layer 108 does not contain a Ga atom and an As atom, a Ga atom and an As atom are never supplied from the diffusion inhibiting layer 108, and the purity of the second semiconductor crystal layer 106 can be enhanced further. In this case, examples of the semiconductor crystal layer forming wafer 102 include a single crystal GaAs wafer and a single crystal Ge wafer, examples of the sacrificial layer 104 include a single crystal AlAs layer, examples of the first semiconductor crystal layer 107 and the second semiconductor crystal layer 106 include a single crystal Ge layer, examples of the diffusion inhibiting layer 108 include a single crystal InAlP layer, and examples of the first atom include a Ga atom and an As atom.

When the first semiconductor crystal layer 107 and the second semiconductor crystal layer 106 are layers made of single crystal Ge, the half-value width of the diffraction spectrum of the (004) plane of the second semiconductor crystal layer 106 may be 40 arcsec or lower when measured using X-ray diffraction. Also, the second semiconductor crystal layer 106 exhibits flatness of 2 nm or less when expressed in terms of the root mean square (RMS). When required, a surface of the second semiconductor crystal layer 106 may be polished. Note that a buffer layer may be formed between the semiconductor crystal layer forming wafer 102 and the sacrificial layer 104. When the semiconductor crystal layer forming wafer 102 is a GaAs wafer, examples of the buffer layer include a GaAs layer.

### Second Embodiment

A method of producing the semiconductor wafer 100 described in the first embodiment is described by referring to a flowchart illustrated in FIG. 5. First, the semiconductor crystal layer forming wafer 102 is loaded into a reaction chamber of an epitaxial growth apparatus (Step 202). As necessary, preprocessing is performed or the temperature of the wafer is raised, the sacrificial layer 104, the diffusion inhibiting layer 108 and the first semiconductor crystal layer 107 are sequentially formed on the semiconductor crystal layer forming wafer 102 (Step 204).

The sacrificial layer 104 can be formed by epitaxial growth, chemical vapor deposition (CVD), sputtering or atomic layer deposition (ALD), etc. The epitaxial growth can include metal organic chemical vapor deposition (MOCVD) or molecular beam epitaxy (MBE). When the sacrificial layer 104 is formed by MOCVD, the source gas can be trimethylgallium (TMGa), trimethylaluminum (TMA), trimethylindium (TMIn), arsine (AsH₃), phosphine (PH₃) or the like. The carrier gas can be hydrogen. Alternatively, a compound that is obtained by replacing some of the hydrogen atom groups of the above-described source gas with a chlorine atom or a hydrocarbon group can be used. The growth temperature (which is also referred to as the reaction temperature) can be selected appropriately within the range of 300° C. to 900° C., preferably within the range of 400° C. to 800° C. The thickness of the sacrificial layer 104 can be controlled by appropriately determining the amount of the source gas to be supplied and the duration of the reaction.

The diffusion inhibiting layer 108 can be formed by epitaxial growth or ALD. The epitaxial growth can include MOCVD and MBE. When the diffusion inhibiting layer 108 is made of a Group III-V compound semiconductor and formed by MOCVD, the source gas can be trimethylgallium (TMGa), trimethylaluminum (TMA), trimethylindium (TMIn), arsine (AsH₃), phosphine (PH₃) or the like. The carrier gas can be hydrogen. Alternatively, a compound that is obtained by replacing some of the hydrogen atom groups of the above-described source gas with a chlorine atom or a hydrocarbon group can be used. The growth temperature can be selected appropriately within the range of 300° C. to 900° C., preferably within the range of 400° C. to 800° C. The thickness of the diffusion inhibiting layer 108 can be controlled by appropriately determining the amount of the source gas to be supplied and the duration of the reaction.

The first semiconductor crystal layer 107 can be formed by epitaxial growth, CVD or ALD. The epitaxial growth can include MOCVD and MBE. When the first semiconductor crystal layer 107 is made of a Group III-V compound semiconductor and formed by MOCVD, the source gas can be trimethylgallium (TMGa), trimethylaluminum (TMA), trimethylindium (TMIn), arsine (AsH₃), PH₃ (phosphine) or the like. When the first semiconductor crystal layer 107 is made of a Group IV compound semiconductor or a Group IV semiconductor and formed by CVD, the source gas can be germane (GeH₄), silane (SiH₄), disilane (Si₂H₆) or the like. The carrier gas can be hydrogen. Alternatively, a compound that is obtained by replacing some of the hydrogen atom groups of the above-described source gas with a chlorine atom or a hydrocarbon group can be used. The growth temperature can be selected appropriately within the range of 300° C. to 900° C., preferably within the range of 400° C. to 800° C. The thickness of the first semiconductor crystal layer 107 can be controlled by appropriately determining the amount of the source gas to be supplied and the duration of the reaction.

When the sacrificial layer 104, the diffusion inhibiting layer 108 and the first semiconductor crystal layer 107 are formed by MOCVD and CVD, these layers can be formed successively. The types of gas are switched to form the respective layers. When the sacrificial layer 104 or the diffusion inhibiting layer 108 is made of a Group III-V compound semiconductor, and the first semiconductor crystal layer 107 that is formed thereafter is made of a Group IV compound semiconductor or a Group IV semiconductor, a purge process to allow only the carrier gas to flow may be provided after formation of the sacrificial layer 104 or the diffusion inhibiting layer 108. The rapidness of compositional changes at the interfaces can be enhanced by providing the purge process. The purge process is preferably performed at a temperature that does not cause decomposition of the sacrificial layer 104 or the diffusion inhibiting layer 108. The temperature of the purge process is preferably 750° C. or lower, and further preferably 650° C. or lower.

Next, the semiconductor crystal layer forming wafer 102 is taken out of the reaction chamber, and placed in a spare room (Step 206). The semiconductor crystal layer forming wafer 102 may be placed not in the spare room, but in an atmospheric environment which is kept clean.

Next, the reaction chamber is cleaned (Step 208). The reaction chamber may be cleaned by etching using halogen-based gas, for example. By cleaning the reaction chamber, the concentration of a residual impurity atom can be lowered. Thereby, the background level of an impurity atom at the time of forming the second semiconductor crystal layer 106 can be lowered, and mixing of an impurity atom into the second semiconductor crystal layer 106 can be suppressed. Examples of the halogen-based gas include hydrogen chloride (HCl), chlorine (Cl₂), carbon tetrafluoride (CF₄), trifluoromethane (CHF₃), and boron trichloride (BXl₃). Also, plasma etching may be used.

Next, the semiconductor crystal layer forming wafer 102 having been placed in the spare room is returned to the reaction chamber (Step 210), and the second semiconductor crystal layer 106 is formed on the first semiconductor crystal layer 107 (Step 212). The formation of the second semiconductor crystal layer 106 is approximately the same with the formation of the first semiconductor crystal layer 107. However, the growth temperature in epitaxial growth for forming the second semiconductor crystal layer 106 is preferably higher than the growth temperature in epitaxial growth for forming the first semiconductor crystal layer 107. Also, the reaction pressure under which the epitaxial growth is performed for forming the second semiconductor crystal layer 106 is preferably lower than the reaction pressure under which epitaxial growth is performed for forming the first semiconductor crystal layer 107. By raising the temperature and lowering the pressure, the surface flatness of the second semiconductor crystal layer 106 can become better than that of the first semiconductor crystal layer 107. After the second semiconductor crystal layer 106 is formed to have predetermined thickness, the semiconductor crystal layer forming wafer 102 is unloaded from the reaction chamber (Step 214), and the processing ends. The growth temperature employed when growing the second semiconductor crystal layer 106 is preferably 600° C. or higher, and further preferably 650° C. or higher. The semiconductor crystal layer surface grown at a temperature of 600° C. or higher has flatness which is suitable for transfer and adhesion. The reaction pressure under which the second semiconductor crystal layer 106 is grown is preferably lower than 40 Torr, more preferably 20 Torr or lower, and further preferably 10 Torr or lower. The semiconductor crystal layer surface grown at the pressure of 40 Torr or lower has flatness that is suitable for transfer and adhesion. Specifically, the second semiconductor crystal layer 106 (Ge crystal layer) can be formed by using monogermane as a raw material, setting the growth temperature at 650° C., and setting the growth pressure at 6 Torr. In this case, examples of the suitable thickness of the second semiconductor crystal layer 106 include 1.4 μm. A surface of the semiconductor crystal layer forming wafer 102 may be heated before growing the second semiconductor crystal layer 106. When the surface of the semiconductor crystal layer forming wafer 102 is a Group IV compound semiconductor or a Group IV semiconductor, it is preferably heated in a hydrogen atmosphere. The surface can be made clean by heating in a hydrogen atmosphere.

Because in the method of producing the semiconductor wafer 100 relating to the second embodiment, the inside of the reaction chamber is cleaned before the second semiconductor crystal layer 106 is formed, mixing of an impurity atom into the second semiconductor crystal layer 106 can be inhibited to a very low level. Thereby, The performance of an electronic device that uses the second semiconductor crystal layer 106 as an active layer can be enhanced. Also, in the production method relating to the second embodiment, the first semiconductor crystal layer 107 is formed before the semiconductor crystal layer forming wafer 102 is placed in the spare room. Because the first semiconductor crystal layer 107 serves as a cap layer that prevents damages or deterioration of a surface while the semiconductor crystal layer forming wafer 102 is placed in the spare room, and the first semiconductor crystal layer 107 is made of a material (crystal) that is similar to the material of the second semiconductor crystal layer 106, the start of growth (nucleation) of the second semiconductor crystal layer 106 becomes easy. The thickness of the first semiconductor crystal layer 107 is preferably 0.1 nm or larger, and 1 μm or smaller. When the thickness is smaller than 0.1 nm, the functionality as a cap layer is not sufficient and thus it is not preferred. Also, when the thickness is larger than 1 μm, the region to which a larger number of an impurity atom is mixed in at the time of transfer becomes larger, and thus a preferred device cannot be obtained.

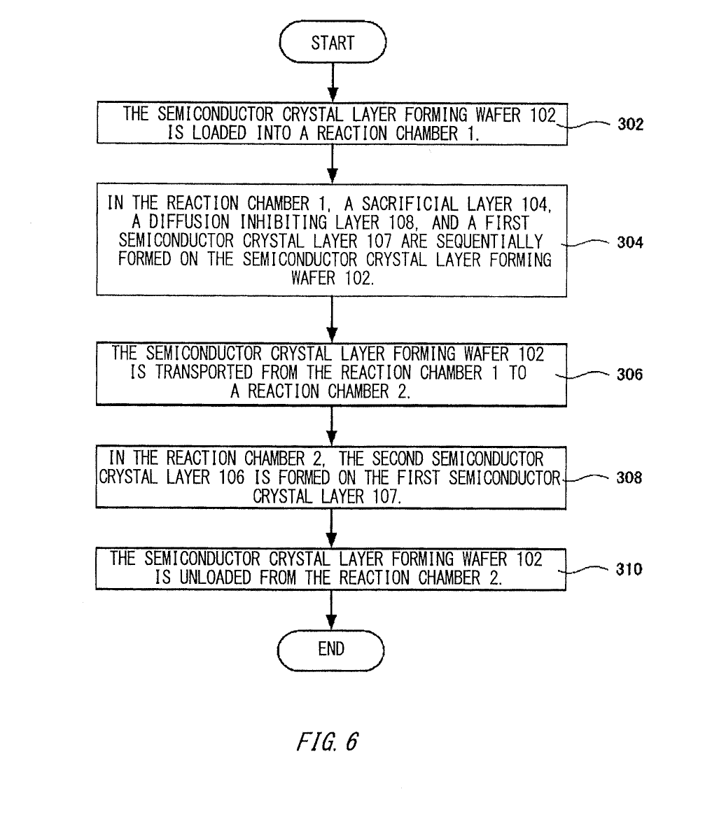

Note that the above-mentioned semiconductor wafer 100 can be produced by steps according to the flowchart illustrated in FIG. 6. That is, the semiconductor crystal layer forming wafer 102 is loaded into a reaction chamber 1 (Step 302), and in the reaction chamber 1, the sacrificial layer 104, the diffusion inhibiting layer 108, and the first semiconductor crystal layer 107 are formed (Step 304) as in Step 204 illustrated in FIG. 5. Thereafter, the semiconductor crystal layer forming wafer 102 is transported from the reaction chamber 1 to a reaction chamber 2 (Step 306). In the reaction chamber 2, as in Step 212 illustrated in FIG. 5, the second semiconductor crystal layer 106 is formed (Step 308) to have a predetermined thickness, and then the semiconductor crystal layer forming wafer 102 is unloaded from the reaction chamber 2 (Step 310).

In the case of the method illustrated in FIG. 6, reaction chambers can be used differently, that is, growth with a high background level of an impurity atom is performed in the reaction chamber 1, and growth with a low background level of an impurity atom is performed in the reaction chamber 2. Thereby, the second semiconductor crystal layer 106 with a low mixed impurity atom concentration can be formed efficiently. Note that while a second semiconductor crystal layer 106 is formed in the reaction chamber 2, a next semiconductor crystal layer forming wafer 102 can be processed in the reaction chamber 1; thereby, the takt time can be shortened. Also, in the case of the production method in FIG. 6, the reaction chamber 1 or the reaction chamber 2 needs not be cleaned after each growth processing. Thereby, cleaning may be performed less frequently; thus, the takt time can be shortened, and the cost can be reduced.

Step 306 of transporting the semiconductor crystal layer forming wafer 102 from the reaction chamber 1 to the reaction chamber 2 in the method of FIG. 6 is preferably performed without vacuum break, but may be performed with vacuum break. Vacuum break refers to that the semiconductor crystal layer forming wafer 102 is exposed to a non-vacuum environment. That is, the transportation of the semiconductor crystal layer forming wafer 102 between the reaction chamber 1 and the reaction chamber 2 may be performed in a multi-chamber growth apparatus equipped with a load-unload chamber that can handle a wafer without vacuum break. Also, the transportation may be performed in two discrete and separate growth apparatuses each having the reaction chamber 1 or the reaction chamber 2. In this case, the semiconductor crystal layer forming wafer 102 may be taken out from a growth apparatus having the reaction chamber 1 to the outside, transported in the air, and introduced into another growth apparatus having the reaction chamber 2. According to a secondary ion mass spectrum (SIMS) analysis performed, it can be known that even in the case of transporting the semiconductor crystal layer forming wafer 102 from the reaction chamber 1 to the reaction chamber 2 with vacuum break, the Ga concentration in the second semiconductor crystal layer 106 becomes lower than the Ga concentration in the first semiconductor crystal layer 107.

### Third Embodiment

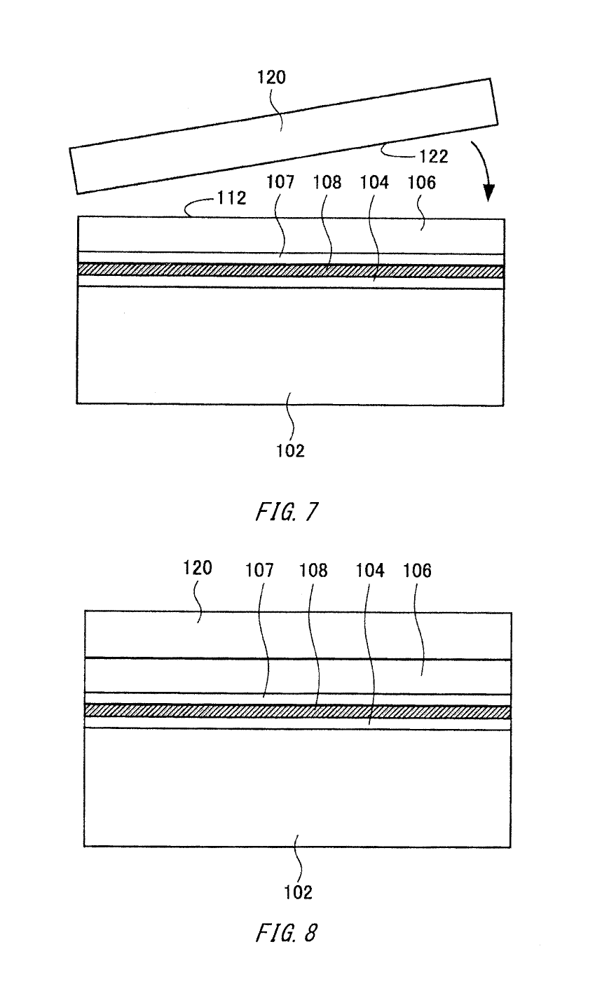

FIGS. 7 to 10 are cross-sectional views illustrating steps of a method of producing a composite wafer relating to a third embodiment in the performed order. The production method relating to the third embodiment uses the semiconductor wafer 100 described in the first embodiment. The semiconductor wafer 100 is prepared as described in the first embodiment.

Next, as illustrated in FIG. 7, a surface of the transfer target wafer 120 and a surface of the second semiconductor crystal layer 106 of the semiconductor crystal layer forming wafer 102 are caused to face each other. Here, the surface of the second semiconductor crystal layer 106 is a surface of a layer formed on the semiconductor crystal layer forming wafer 102, and is an example of a “first surface 112” which is to contact the transfer target wafer 120 or a layer formed on the transfer target wafer 120. Also, the surface of the transfer target wafer 120 is a surface of the transfer target wafer 120 or a layer formed on the transfer target wafer 120, and is an example of a “second surface 122” which is to contact the first surface 112.

The transfer target wafer 120 is a wafer to which the second semiconductor crystal layer 106, the first semiconductor crystal layer 107, and the diffusion inhibiting layer 108 are to be transferred. The transfer target wafer 120 can be a target wafer on which an electronic device that uses the second semiconductor crystal layer 106 as an active layer is eventually formed, or a provisional wafer on which the second semiconductor crystal layer 106 is temporarily placed until the second semiconductor crystal layer 106 is transferred onto the target wafer. That is, the second semiconductor crystal layer 106 may be transferred from the transfer target wafer 120 further to another wafer. The transfer target wafer 120 may be made of any of organic materials or inorganic materials. Examples of the transfer target wafer 120 include a silicon wafer, a silicon-on-insulator (SOI) wafer, a glass wafer, a sapphire wafer, an SiC wafer, and an AlN wafer. Alternatively, the transfer target wafer 120 may be an insulative wafer such as a ceramics wafer or a plastic wafer, or an electrically-conductive wafer made of a metal, for example. When the transfer target wafer 120 is a silicon wafer or SOI wafer, a production apparatus that is used for existing silicon processes can be used. The research, development and production can be conducted more efficiently utilizing the common knowledge known in the field of silicon processes.

When the transfer target wafer 120 is a hard wafer that does not easily bend, such as a silicon wafer, the second semiconductor crystal layer 106 to be transferred is protected against mechanical vibration and the like and the high crystallinity of the second semiconductor crystal layer 106 can be maintained. When the transfer target wafer 120 is a flexible wafer such as a plastic wafer, the transfer target wafer 120 and the semiconductor crystal layer forming wafer 102 can be quickly separated by bending the flexible wafer in the direction of separating from the semiconductor crystal layer forming wafer 102, and supplying an etching solution promptly, at a step of etching the sacrificial layer 104 described later.

As illustrated in FIG. 8, the transfer target wafer 120 is bonded to the semiconductor crystal layer forming wafer 102 in such a manner that the surface of the second semiconductor crystal layer 106, which is the first surface 112, is bonded to the surface of the transfer target wafer 120, which is the second surface 122.

At the time of bonding, adhesiveness enhancement treatment to enhance the adhesiveness between the transfer target wafer 120 and the second semiconductor crystal layer 106 may be performed on the surface of the transfer target wafer 120 (the second surface 122) and the surface of the second semiconductor crystal layer 106 (the first surface 112). The adhesiveness enhancement treatment may be performed only on one of the surface of the transfer target wafer 120 (the second surface 122) and the surface of the second semiconductor crystal layer 106 (the first surface 112). The adhesiveness enhancement treatment can be, for example, ion beam activation performed by an ion beam generator. The applied ions are, for example, argon ions. The adhesiveness enhancement treatment may be plasma activation. The plasma activation can be, for example, an oxygen plasma treatment. The adhesiveness enhancement treatment can contribute to the enhancement of the adhesiveness between the transfer target wafer 120 and the second semiconductor crystal layer 106. The adhesiveness enhancement treatment may be replaced with a step of forming in advance an adhesive layer on the transfer target wafer 120. When the adhesiveness enhancement treatment is performed, the bonding step can be performed at room temperature.

Also, following the bonding, the transfer target wafer 120 may be attached onto the semiconductor crystal layer forming wafer 102 under pressure by applying a load to the transfer target wafer 120 and the semiconductor crystal layer forming wafer 102. The step of attaching under pressure can contribute to the improvement of the adhesiveness strength. During or after the step of attaching under pressure, a thermal treatment may be performed. The temperature at which the thermal treatment takes place is preferably within the range of 50° C. to 600° C., further preferably within the range of 100° C. to 400° C. The load can be selected as appropriate within the range of 1 MPa to 1 GPa. Note that, when the transfer target wafer 120 is attached onto the semiconductor crystal layer forming wafer 102 using an adhesive layer, the attaching step under pressure is not necessary.

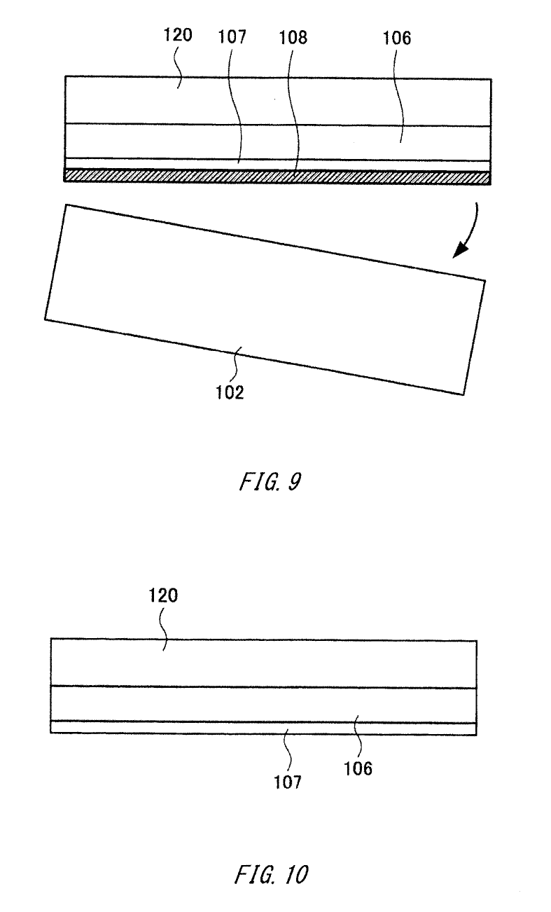

Subsequently, as shown in FIG. 9, the semiconductor crystal layer forming wafer 102 and the transfer target wafer 120 are entirely or partially (preferably, entirely) immersed into an etching solution to etch the sacrificial layer 104. If the sacrificial layer 104 is etched away, the transfer target wafer 120 can be separated from the semiconductor crystal layer forming wafer 102 with the second semiconductor crystal layer 106, the first semiconductor crystal layer 107, and the diffusion inhibiting layer 108 are left on the transfer target wafer 120.

The sacrificial layer 104 can be selectively etched away. Here, the expression “to selectively etch away” means that the sacrificial layer 104 is “selectively” etched away substantially alone by selecting the etching solution and other conditions in such a manner that the sacrificial layer 104 and other constituents, for example, the second semiconductor crystal layer 106, the first semiconductor crystal layer 107 and the diffusion inhibiting layer 108 are similarly exposed to the etching solution and etched away but the etching rate of the sacrificial layer 104 is controlled to be higher than the etching rate of the other constituents. When the sacrificial layer 104 is an AlAs layer, the etching solution can be, for example, HCl, HF, phosphoric acid, citric acid, hydrogen peroxide solution, ammonia, an aqueous solution of sodium hydroxide or water. During the etching, the temperature is preferably controlled to fall within the range of 10° C. to 90° C. The duration of the etching can be controlled as appropriate to fall within the range of 1 minute to 200 hours.

The sacrificial layer 104 can also be etched away with an ultrasonic wave being applied to the etching solution. The application of an ultrasonic wave can increase the etching rate. Furthermore, while the etching is being performed, a ultraviolet ray may be applied or the etching solution may be stirred. Here, the above describes an exemplary case where the sacrificial layer 104 is etched using the etching solution. However, the sacrificial layer 104 can be etched away using dry etching.

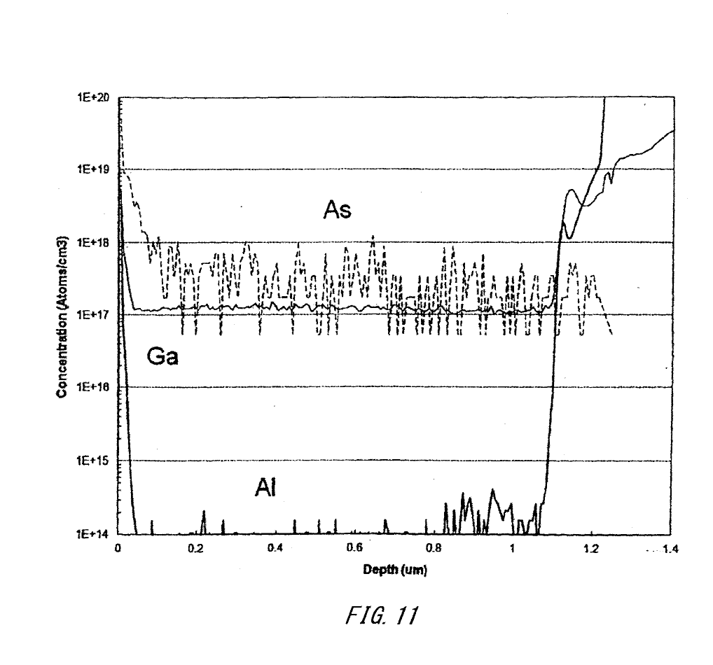

If the sacrificial layer 104 is removed by the etching in the above-described manner, the transfer target wafer 120 is separated from the semiconductor crystal layer forming wafer 102 with the second semiconductor crystal layer 106, the first semiconductor crystal layer 107 and the diffusion inhibiting layer 108 being left on the transfer target wafer 120. Thus, the second semiconductor crystal layer 106 is transferred onto the transfer target wafer 120. When the diffusion inhibiting layer 108 is removed, a composite wafer having the second semiconductor crystal layer 106 and the first semiconductor crystal layer 107 is produced on the transfer target wafer 120 as illustrated in FIG. 10. Note that the first semiconductor crystal layer 107 can serve as a cap layer until the second semiconductor crystal layer 106 is used. Because an impurity atom is mixed in the first semiconductor crystal layer 107 at a high concentration, it is desirably removed at the time of producing a device. Etching may be dry etching, wet etching or the like. When the first semiconductor crystal layer 107 is a Ge layer, etchant used may be phosphoric acid or citric acid to which a hydrogen peroxide solution is added. The surface of the second semiconductor crystal layer 106 can be easily exposed by providing an etching stop layer made of another material between the first semiconductor crystal layer 107 and the second semiconductor crystal layer 106 to perform etching selectively. The separated semiconductor crystal layer forming wafer 102 can be reused as a wafer for forming a semiconductor crystal layer after performing processing such as polishing or cleaning. As a result, the production cost can be lowered.

In the above-mentioned method of producing the composite wafer relating to the third embodiment, the high quality second semiconductor crystal layer 106 with a low impurity atom concentration can be formed on the transfer target wafer 120.

Note that although in the above-mentioned third embodiment, the second semiconductor crystal layer 106 is transferred from the semiconductor crystal layer forming wafer 102 to the transfer target wafer 120, it may be transferred further to another transfer target wafer. Also, an adhesive layer may be formed between the second semiconductor crystal layer 106 and the transfer target wafer 120 as appropriate. The adhesive layer may be made of organic materials or inorganic materials. Examples of the organic material adhesive layer include a polyimide film or a resist film. In this case, the adhesive layer can be formed by coating such as spin coating. When made of an inorganic material, the adhesive layer can be, for example, a layer made of at least one of Al₂O₃, AlN, Ta₂O₅, ZrO₂, HfO₂, SiOₓ (for example, SiO₂), SiNₓ (for example, Si₃N₄), and SiOₓN_{y}, or a laminate obtained by stacking at least two layers respectively made of the above-listed materials. In this case, the adhesive layer can be formed by ALD, thermal oxidation, evaporation, CVD or sputtering. The thickness of the adhesive layer can be within the range of 0.1 nm to 100 μm.

Also, after the sacrificial layer 104, the diffusion inhibiting layer 108, the first semiconductor crystal layer 107, and the second semiconductor crystal layer 106 are formed on the semiconductor crystal layer forming wafer 102 and before the semiconductor crystal layer forming wafer 102 and the transfer target wafer 120 are bonded to each other, an electronic device whose active region is constituted by a portion of the second semiconductor crystal layer 106 may be formed on the second semiconductor crystal layer 106. In this case, the second semiconductor crystal layer 106 is transferred with the electronic device being formed thereon. Since the second semiconductor crystal layer 106 is flipped each time it is transferred, this method enables electronic devices to be formed on both of the front and back planes of the second semiconductor crystal layer 106.

In the above description of the embodiments, the final wafer to which the second semiconductor crystal layer 106 is eventually transferred is not specifically mentioned. The final wafer may be a semiconductor wafer such as a silicon wafer, an SOI wafer or a wafer in which a semiconductor layer is formed on an insulative wafer. On the semiconductor wafer, the SOI layer or the semiconductor layer, an electronic device such as a transistor may be formed in advance. In other words, the second semiconductor crystal layer 106 can be formed by the transfer technique using the above-described methods on the wafer on which the electronic device has already been formed. Using this technique, semiconductor devices that are significantly different in composition, material or the like can be monolithically formed. In particular, if an electronic device is formed in advance on the second semiconductor crystal layer 106, and the second semiconductor crystal layer 106 is subsequently formed by the transfer technique on the above-described wafer on which an electronic device has already been formed, the electronic devices that are made of heterogeneous materials and produced using significantly different production processes can be easily monolithically formed.

### Example 1

In Example 1, a specific method of producing a high quality Ge crystal layer, and a result obtained by measuring characteristics of the produced Ge crystal layer are described. As the semiconductor crystal layer forming wafer 102, a GaAs wafer having a 150 mm diameter and a 2° inclination from the (100) plane to the (110) plane was used. An AlAs crystal layer as the sacrificial layer 104 was formed on the GaAs wafer by using epitaxial growth by low-pressure MOCVD, and a Ge crystal layer as the first semiconductor crystal layer 107 was formed by using epitaxial growth by low pressure CVD. The AlAs crystal layer was formed by crystal growth at the growth temperature of 600° C. with trimethylaluminum (which may be referred to as TMAl in the present specification), and arsine (which may be referred to as AsH₃ in the present specification) as its raw materials. Thereafter, the Ge crystal layer (the first semiconductor crystal layer 107) was formed by growing a Ge crystal with monogermane (which may be referred to as GeH₄ in the present specification) as its raw material. The growth temperature was 550° C., and the reaction pressure was 40 Torr. The AlAs crystal layer and the Ge crystal layer were formed over the entire surface of the GaAs wafer. The thickness of the AlAs crystal layer and the Ge crystal layer was 150 nm and 100 nm, respectively.

Next, as a measure to reduce a residual impurity atom before formation of the second semiconductor crystal layer 106, the semiconductor crystal layer forming wafer 102 was taken out of a reaction chamber and placed in a spare room (Step 206). Next, the reaction chamber was cleaned by etching using hydrogen chloride gas (Step 208). Next, the semiconductor crystal layer forming wafer 102 having been placed in the spare room was returned to the reaction chamber (Step 210). On the first semiconductor crystal layer 107, the second semiconductor crystal layer 106 (Ge crystal layer) was formed to have a thickness of 1.4 μm with monogermane as its raw material (Step 212). The growth temperature was 650° C., and the growth pressure was 6 Torr. The semiconductor crystal layer forming wafer 102 was unloaded from the reaction chamber (Step 214), and the processing ended.

FIG. 11 is a graph showing a result of secondary ion mass spectrum (SIMS) analysis of the thus-obtained semiconductor crystal layer forming wafer 102 in Example 1. While the Ga concentration in the Ge crystal layer which was the second semiconductor crystal layer 106 was 1×10¹⁷ cm⁻³, the Ga concentration in the Ge crystal layer which was the first semiconductor crystal layer 107 was as high as 2×10¹⁸ cm⁻³ or higher. It can be known that the Ga concentration in the Ge crystal layer which was the second semiconductor crystal layer 106 was kept low. Also, the surface flatness of the Ge crystal layer which was the second semiconductor crystal layer 106 on the obtained semiconductor crystal layer forming wafer 102 as measured by an atomic force microscope (AFM) was 1.8 nm when expressed in terms of the root mean square (RMS) of a 10×10 μm region. Also, the half-value width of the diffraction spectrum of the (004) plane of the obtained semiconductor crystal layer forming wafer 102 was 27.9 arcsec when measured using X-ray diffraction.

### Example 2

Other than that the growth temperature of the Ge crystal layer which was the second semiconductor crystal layer 106 was set to 550° C., growth was performed under the same conditions as in Example 1. The result of secondary ion mass spectrum (SIMS) analysis of the obtained semiconductor crystal layer forming wafer 102 showed the Ga concentration in the Ge crystal layer which was the second semiconductor crystal layer 106 being 1×10¹⁷ cm⁻³, and the Ga concentration in the Ge crystal layer which was the first semiconductor crystal layer 107 being 2×10¹⁸ cm⁻³ or more.

### Comparative Example 1

The AlAs sacrificial layer and the Ge crystal layer which was the first semiconductor crystal layer 107 were grown as in Example 1, and the Ge crystal layer which was the second semiconductor crystal layer 106 was grown without cleaning of the inside of a furnace. The result of secondary ion mass spectrum (SIMS) analysis of the obtained semiconductor crystal layer forming wafer 102 showed the Ga concentration in the Ge crystal layer which was the second semiconductor crystal layer 106 being 6 to 8×10¹⁸ cm⁻³, and the Ga concentration in the Ge crystal layer which was the first semiconductor crystal layer 107 being 5 to 6×10¹⁸ cm⁻³. A significant difference could not be observed.

### Example 3

Other than that the growth temperature at the time of growing the Ge crystal layer which was the second semiconductor crystal layer 106 was set to 550° C., growth was performed under the same conditions as in Example 1, and the semiconductor crystal layer forming wafer 102 having the same film thickness as in Example 1 was fabricated. The surface flatness of the obtained semiconductor crystal layer forming wafer 102 as measured by an atomic force microscope was 3.2 nm when expressed in terms of the root mean square (RMS) of a 10×10 μm region.

### Example 4

Other than that the growth temperature at the time of growing the Ge crystal layer which was the second semiconductor crystal layer 106 was set to 700° C., growth was performed under the same conditions as in Example 1, and the semiconductor crystal layer forming wafer 102 was fabricated. The surface flatness of the obtained semiconductor crystal layer forming wafer 102 as measured by an atomic force microscope was 0.5 nm when expressed in terms of the root mean square (RMS) of a 10×10 μm region.

### Example 5

Other than that the reaction pressure at the time of growing the Ge crystal layer which was the second semiconductor crystal layer 106 was changed, a semiconductor crystal layer forming wafer was fabricated under the same conditions as in Example 2. The Ge crystal layer which was the second semiconductor crystal layer 106 was formed with the reaction pressure of 10 Torr, 20 Torr, 40 Torr, and 80 Torr. The surface flatness of the semiconductor crystal layer forming wafer 102 grown at 10 Torr, 20 Torr, and 40 Torr as measured by an atomic force microscope was 2.6 nm, 2.1 nm, and 6.3 nm, respectively, when expressed in terms of the root mean square (RMS) of a 10×10 μm region, and the semiconductor crystal layer forming wafer 102 grown at 80 Torr showed a cloud on its surface.

### Example 6

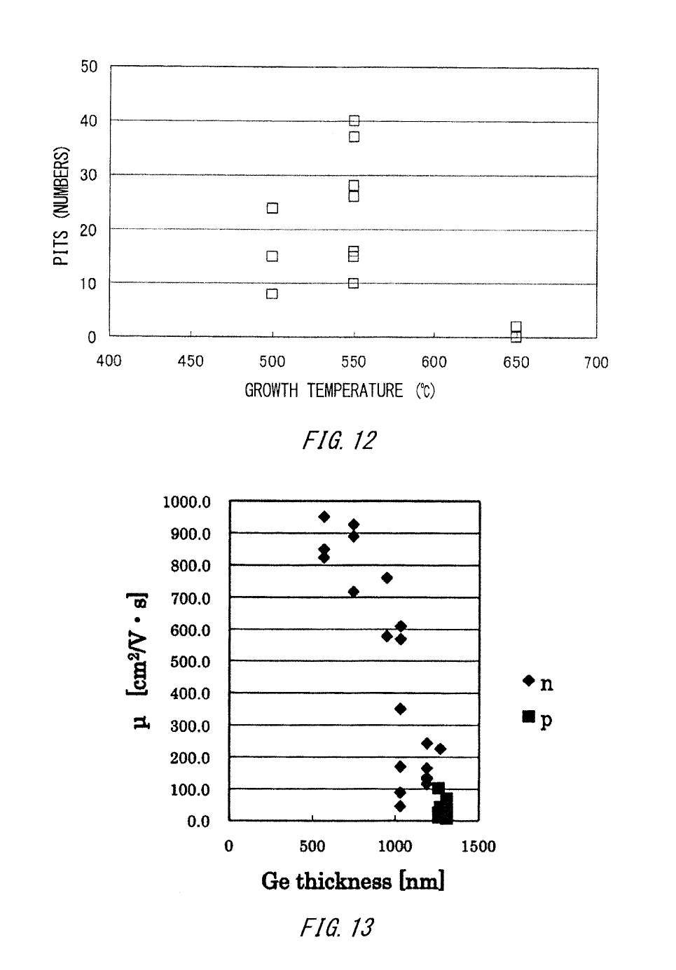

An AlAs sacrificial layer was grown on the semiconductor crystal layer forming wafer 102 at the growth temperature of 600° C., a Ge crystal layer which was the first semiconductor crystal layer 107 was formed thereon at 550° C., and a Ge crystal layer which was the second semiconductor crystal layer 106 was formed further thereon. The growth temperature at the time of growing the Ge crystal layer which was the second semiconductor crystal layer 106 was 500° C., 550° C. and 650° C., the surface was observed with an optical microscope, and the number of pits that are present on the surface within the range of 1.40×1.05 mm was evaluated. The results are shown in FIG. 12. According to the results, it could be known that the number of pits on a surface can be reduced by setting the growth temperature to 650° C., as compared with the growth temperature of 500° C. and 550° C.

### Example 7

A sample obtained in Example 1 was transferred onto a Si wafer according to the steps of the third embodiment. A composite wafer having the second semiconductor crystal layer 106 and the first semiconductor crystal layer 107 was produced on the Si wafer. Hall measurement was performed while etching the obtained composite wafer from the side of the first semiconductor crystal layer 107, and values of the mobility of the respective film thickness were obtained. FIG. 13 is a graph showing a correlation between the mobility (μ) obtained in the hall measurement and the film thickness (Ge thickness).

Highly concentrated p-type was observed near the surface of the first semiconductor crystal layer 107 (the film thickness of about 1300 nm in FIG. 13). As shown in FIG. 11, a Ga atom or an Al atom (impurity atom), defect or the like are mixed in the first semiconductor crystal layer 107 (Ge crystal layer), and it is assumed that the mixing of the impurity atom and defects caused the highly concentrated p-type. When the first semiconductor crystal layer 107 (the Ge crystal layer) is removed completely by etching, and only the second semiconductor crystal layer 106 is present on the Si wafer (the film thickness of about 1200 nm in FIG. 13), the Ge crystal layer becomes n-type.

When etching was further performed, and the film thickness of the second semiconductor crystal layer 106 (the film thickness in FIG. 13) becomes 700 nm or smaller, the mobility (electron mobility) begins to show constant values of 800 cm²/V·s or higher. The electron density of this film thickness is approximately 2×10¹⁷/cm³, and this approximately corresponds to the level of an As atom which serves as the n-type dopant obtained from the SIMS analysis shown in FIG. 11

The obtained measurement value of mobility was 950 cm²/V·s at most. This value corresponds to approximately 80% of the value of a single crystal wafer. As described above, it was demonstrated that a high quality second semiconductor crystal layer 106 with a low impurity atom concentration can be formed on any wafer.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor wafer comprising a sacrificial layer, a first semiconductor crystal layer, and a second semiconductor crystal layer above a semiconductor crystal layer forming wafer, wherein
the semiconductor crystal layer forming wafer, the sacrificial layer, the first semiconductor crystal layer and the second semiconductor crystal layer are arranged in the order of the semiconductor crystal layer forming wafer, the sacrificial layer, the first semiconductor crystal layer and the second semiconductor crystal layer,
a first atom of one type selected from a plurality of types of atoms constituting the semiconductor crystal layer forming wafer or the sacrificial layer is contained in the first semiconductor crystal layer and the second semiconductor crystal layer as an impurity, and
the concentration of the first atom in the second semiconductor crystal layer is lower than the concentration of the first atom in the first semiconductor crystal layer.

2. The semiconductor wafer as set forth in claim 1, further comprising a diffusion inhibiting layer that inhibits diffusion of the first atom at any cross-sectional position between (a) the interface of the semiconductor crystal layer forming wafer that faces the sacrificial layer and (b) a middle of the second semiconductor crystal layer.

3. The semiconductor wafer as set forth in claim 1, wherein
the semiconductor crystal layer forming wafer is made of single-crystal GaAs or single-crystal Ge,
the sacrificial layer is made of a Group III-V semiconductor, and
the first semiconductor crystal layer and the second semiconductor crystal layer are made of a Group IV semiconductor.

4. The semiconductor wafer as set forth in claim 3, wherein
the sacrificial layer is made of AlₐGa_{b}In_{(1-a-b)}As (0.9≦a≦1, 0≦b≦0.1, 0.9≦a+b≦1), and
the first semiconductor crystal layer and the second semiconductor crystal layer are made of C_{d}SiₑGe_{f}Sn_{(1-d-e-f)} (0≦d<1, 0≦e<1, 0<f≦1, 0<d+e+f≦1).

5. The semiconductor wafer as set forth in claim 4, wherein
the semiconductor crystal layer forming wafer is made of single-crystal GaAs,
the sacrificial layer is made of single-crystal AlAs,
the first semiconductor crystal layer and the second semiconductor crystal layer are made of single-crystal Ge, and
the first atom is an Al, Ga or As atom.

6. The semiconductor wafer as set forth in claim 5, wherein
the concentration of a Ga atom in the second semiconductor crystal layer is lower than 2×10¹⁷ [atom/cm³].

7. The semiconductor wafer as set forth in claim 5, wherein
the half-value width of the diffraction spectrum of the (004) plane of the second semiconductor crystal layer that is made of the single-crystal Ge is 40 arcsec or lower when measured using X-ray diffraction.

8. The semiconductor wafer as set forth in claim 7, wherein
the second semiconductor crystal layer exhibits flatness of 2 nm or less when expressed in terms of the root mean square (RMS).

9. A method of producing a semiconductor wafer, comprising:
forming a sacrificial layer and a first semiconductor crystal layer in the order of the sacrificial layer and the first semiconductor crystal layer by epitaxial growth above a semiconductor crystal layer forming wafer;
reducing a residual impurity atom resulting from the epitaxial growth after the formation of the sacrificial layer and the first semiconductor crystal layer; and
forming a second semiconductor crystal layer above the first semiconductor crystal layer by epitaxial growth after the reduction of the residual impurity atom.

10. The method as set forth in claim 9 of producing a semiconductor wafer, wherein
the reduction of the residual impurity atom is performed to achieve the reduced residual impurity atom at a start of the epitaxial growth for the formation of the second semiconductor crystal layer when compared with the residual impurity atom resulting from the epitaxial growth for the formation of the sacrificial layer and the first semiconductor crystal layer.

11. The method as set forth in claim 10 of producing a semiconductor wafer, wherein
the reduction of the residual impurity atom is achieved by internal cleaning of an epitaxial growth furnace that is used for the epitaxial growth for the formation of the sacrificial layer and the first semiconductor crystal layer and the epitaxial growth for the formation of the second semiconductor crystal layer.

12. The method as set forth in claim 11 of producing a semiconductor wafer, wherein
the internal cleaning of the epitaxial growth furnace is performed after the semiconductor crystal layer forming wafer is transferred to a spare chamber, and
the semiconductor crystal layer forming wafer is transferred to the epitaxial growth furnace from the spare chamber after the internal cleaning of the epitaxial growth furnace is completed.

13. The method as set forth in claim 10 of producing a semiconductor wafer, wherein
the reduction of the residual impurity atom is performed by transferring the semiconductor crystal layer forming wafer from a first epitaxial growth furnace used for the epitaxial growth for the formation of the sacrificial layer and the first semiconductor crystal layer to a second epitaxial growth furnace used for the epitaxial growth for the formation of the second semiconductor crystal layer.

14. The method as set forth in claim 9 of producing a semiconductor wafer, wherein
the growth temperature at which the epitaxial growth is performed for forming the second semiconductor crystal layer is higher than the growth temperature at which the epitaxial growth is performed for forming the first semiconductor crystal layer.

15. The method as set forth in claim 9 of producing a semiconductor wafer, wherein
the reaction pressure under which the epitaxial growth is performed for forming the second semiconductor crystal layer is lower than the reaction pressure under which the epitaxial growth is performed for forming the first semiconductor crystal layer.

16. The method as set forth in claim 9, further comprising
prior to or during the formation of the sacrificial layer and the first semiconductor crystal layer, or between the formation of the sacrificial layer and the first semiconductor crystal layer and the reduction of the residual impurity atom, forming a diffusion inhibiting layer to inhibit diffusion of a first atom of one type selected from a plurality of types of atoms constituting the sacrificial layer or the semiconductor crystal layer forming wafer.

17. A method of producing a composite wafer using the semiconductor wafer produced by the method as set forth in claim 9, comprising:
bonding the semiconductor wafer and a transfer target wafer in such a manner that a first surface of the semiconductor wafer faces a second surface of the transfer target wafer, the first surface being a surface of the second semiconductor crystal layer or a surface of a layer formed above the second semiconductor crystal layer, the first surface being designed to be brought into contact with the transfer target wafer or a layer formed on the transfer target wafer, the second surface being a surface of the transfer target wafer or a surface of the layer formed on the transfer target wafer, and the second surface being designed to be brought into contact with the first surface; and
etching the sacrificial layer by entirely or partly immersing the semiconductor wafer and the transfer target wafer into an etching solution so that the transfer target wafer and the semiconductor wafer are separated from each other with the first semiconductor crystal layer and the second semiconductor crystal layer being left on the transfer target wafer.
